(19) United States
(12) Patent Application Publication
(10) Pub. No.: US 2015/0340585 A1
(43) Pub. Date: Nov. 26, 2015

(54) DRIVING APPARATUS OF PIEZO ACTUATOR AND METHOD OF DRIVING THE SAME

(71) Applicant: SAMSUNG ELECTRO-MECHANICS CO., LTD., Suwon-Si (KR)

(72) Inventor: Chan Woo PARK, Suwon-Si (KR)

(21) Appl. No.: 14/462,129

(22) Filed: Aug. 18, 2014

(30) Foreign Application Priority Data
May 22, 2014 (KR) 10-2014-0061635

(51) Int. Cl. H01L 41/04

(52) U.S. Cl. CPC H01L 41/042

(57) ABSTRACT

A driving apparatus of a piezo actuator may include: a frequency controlling unit generating a driving frequency signal by sweeping a natural vibration frequency, and a piezo driving unit driving the piezo actuator according to the driving frequency signal by providing the driving frequency signal to the piezo actuator. The driving frequency signal may be in the range of ±5% of the natural vibration frequency.

### CROSS-REFERENCE TO RELATED APPLICATION

This application claims the benefit of Korean Patent Application No. 10-2014-0061635 filed on May 22, 2014, with the Korean Intellectual Property Office, the disclosure of which is incorporated herein by reference.

### BACKGROUND

The present disclosure relates to a driving apparatus of a piezo actuator and a method of driving the same.

Haptic technology is a technology of providing a user with touch feedback though generating vibrations, force, or impacts in a variety of digital devices. Recently, as emotional user interface technology has been developed, the haptic technology aims to be capable of feeding back emotions as well as simply indicating a received signal.

Particularly, in order to implement an emotional user interface, haptic technology has been gradually developed. High definition (HD) haptic technology provides a user with an effect of actually feeling an object through various frequency bands and abundant three-dimensional vibrations.

In order to implement HD haptic technology, a piezo actuator has been used, having faster response speeds, reduced noise, and a higher resonance bandwidth than a linear actuator.

However, due to a characteristic of such a piezo actuator in which it is operated upon being resonant at a voltage of 10V or more, if a driving signal is not tuned to an accurate natural vibration frequency, the piezo actuator may not be normally operated or may have significantly degraded operating efficiency.

Therefore, it is necessary to accurately tune the natural vibration frequency in order to operate such a piezo actuator normally, but since a band of the natural vibration frequency is very narrow and distribution of the natural vibration frequency is large upon being manufactured, it is difficult to accurately tune the natural vibration frequency. Further, characteristics of the piezo actuator may be varied depending on a change in temperature and environmental conditions.

### RELATED ART DOCUMENT

Korean Patent Laid-Open Publication No. 10-2010-0104082

### SUMMARY

An exemplary embodiment in the present disclosure may provide a driving apparatus of a piezo actuator and a method of driving the same capable of maintaining constant displacement characteristics even in a case in which a temperature and surrounding environmental conditions are changed, by sweeping a natural vibration frequency to generate a driving frequency signaldriving frequency signal signal and driving the piezo actuator according to the driving frequency signaldriving frequency signal signal.

According to an exemplary embodiment in the present disclosure, a driving apparatus of a piezo actuator may include: a frequency controlling unit generating a driving frequency signaldriving frequency signal signal by sweeping a natural vibration frequency; and a piezo driving unit driving the piezo actuator according to the driving frequency signaldriving frequency signal signal by providing the driving frequency signal to the piezo actuator, wherein the driving frequency signal is in the range of ±5% of the natural vibration frequency.

According to an exemplary embodiment in the present disclosure, a method of driving a piezo actuator may include: generating a driving frequency signal by sweeping a natural vibration frequency; providing the driving frequency signal to the piezo actuator; and driving the piezo actuator according to the driving frequency signal, wherein the driving frequency signal is in a range of ±5% of the natural vibration frequency.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a block diagram illustrating a driving apparatus of a piezo actuator according to an exemplary embodiment of the present disclosure;

FIG. 2 is a block diagram illustrating the driving apparatus of the piezo actuator shown in FIG. 1 in more detail;

FIG. 3 is a block diagram illustrating a piezo driving unit according to an exemplary embodiment of the present disclosure in more detail;

FIG. 4A is a graph illustrating an analog control signal output from a digital to analog converting unit and FIG. 4B is a graph illustrating a signal output from a filtering unit;

FIG. 5 is a block diagram illustrating the driving apparatus of the piezo actuator shown in FIG. 1 in more detail;

FIG. 6 is a graph illustrating displacement in a case in which a piezo actuator is driven by a driving apparatus of a piezo actuator according to the related art;

FIG. 7 is a graph illustrating a natural vibration frequency that is swept and output by the driving apparatus of the piezo actuator according to an exemplary embodiment of the present disclosure;

FIG. 8 is a flow chart illustrating a method of driving a piezo actuator according to an exemplary embodiment of the present disclosure; and

FIG. 9 is a flow chart illustrating a method of driving a piezo actuator according to an exemplary embodiment of the present disclosure.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. Throughout the drawings, the same or like reference numerals will be used to designate the same or like elements.

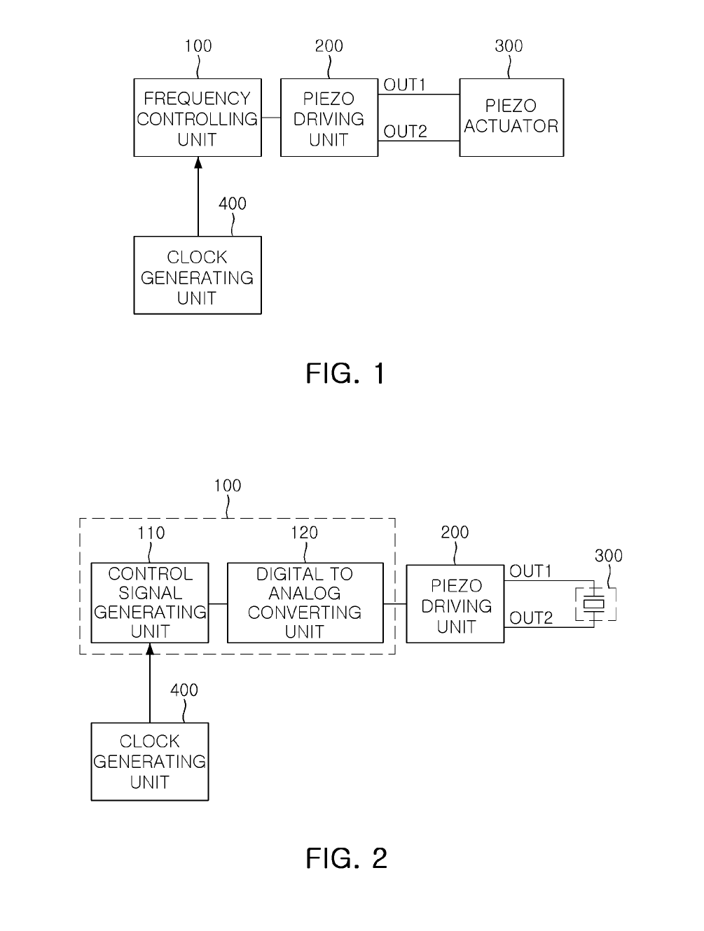

FIG. 1 is a block diagram illustrating a driving apparatus of a piezo actuator according to an exemplary embodiment of the present disclosure.

Referring to FIG. 1, the driving apparatus of the piezo actuator according to an exemplary embodiment of the present disclosure may include a frequency controlling unit 100 and a piezo driving unit 200.

The frequency controlling unit 100 may generate a driving frequency signal by sweeping a natural vibration frequency. The piezo driving unit 200 may be connected to the frequency controlling unit 100 and receive the driving frequency signal. In this case, the piezo driving unit 200 may drive a piezo actuator 300 according to the received driving frequency signal.

In this case, the driving frequency signal may be in the range of ±5% of the natural vibration frequency by way of example.

Further, the driving apparatus of the piezo actuator according to an exemplary embodiment of the present disclosure may further include a clock generating unit 400 providing a driving clock to the frequency controlling unit 100.

The clock generating unit 400 may generate the driving clock by changing a preset reference clock to the range of ±5% and provide the generated driving clock to the frequency controlling unit 100.

The frequency controlling unit 100 may generate the driving frequency signal by sweeping the natural vibration frequency according to the driving clock.

FIG. 2 is a block diagram illustrating the driving apparatus of the piezo actuator shown in FIG. 1 in more detail.

Referring to FIG. 2, the frequency controlling unit 100 may include a control signal generating unit 110 and a digital to analog converting unit 120.

The control signal generating unit 110 may generate a digital control signal having a driving frequency signal. In this case, the driving frequency signal may be generated by sweeping the natural vibration frequency according to the driving clock provided from the clock generating unit 400. The digital control signal may be a digital control signal having certain preset bits and may be a signal having 10 bits by way of example.

The digital to analog converting unit 120 may be connected to the control signal generating unit 110 to receive the digital control signal. The digital to analog converting unit 120 may convert the received digital control signal into an analog control signal. In this case, the analog control signal may be a voltage signal, and the digital to analog converting unit 120 may provide the analog control signal to the piezo driving unit 200.

In further detail, the digital to analog converting unit 120 may generate an analog control signal having a voltage form according to a digital level of the digital control signal. In detail, the digital to analog converting unit 120 may generate the analog control signal having a level of 0 in the case in which the digital level of the digital control signal is an intermediate level, generate the analog control signal having a minus maximum value in the case in which the digital level is a minimum level, and generate the analog control signal having a plus maximum value in the case in which the digital level is a maximum level.

For example, assuming that the digital control signal is a digital signal having 10 bits and the digital to analog converting unit 120 may output the analog control signal in the range of voltage values of −100 to +100, in a case in which the digital to analog converting unit 120 receives the digital control signal of 0, the digital to analog converting unit 120 may output the analog control signal having the voltage value of −100.

In addition, in a case in which the digital to analog converting unit 120 receives the digital control signal of 512 bits, the digital to analog converting unit 120 may output the analog control signal having the voltage value of 0 and in a case in which the digital to analog converting unit 120 receives the digital control signal of 1023 bits, it may output the analog control signal having the voltage value of +100.

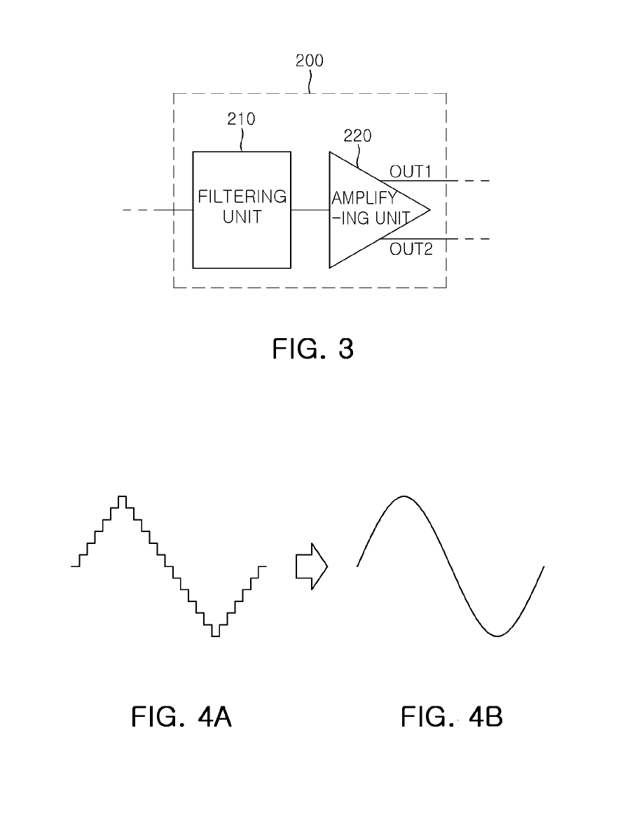

FIG. 3 is a block diagram illustrating a piezo driving unit 200 according to an exemplary embodiment of the present disclosure in more detail.

Referring to FIG. 3, the piezo driving unit 200 may include a filtering unit 210 and an amplifying unit 220.

The filtering unit 210 may be connected to the digital to analog converting unit 120 and filter the analog control signal provided from the digital to analog converting unit 120.

The amplifying unit 220 may be connected to the filtering unit 210 and may perform inverting amplification and non-inverting amplification on the analog control signal provided from the filtering unit 210, based on a common voltage, to generate first and second driving signals.

In further detail, the amplifying unit 220 may generate a first driving signal obtained by performing the non-inverting amplification on the analog control signal and a second driving signal obtained by performing the inverting amplification for the analog control signal. Next, the amplifying unit 220 may drive the piezo actuator 300 by applying the respective first and second driving signals to both terminals of the piezo actuator 300. In this case, the first driving signal may be output from a first output terminal OUT1 of the piezo driving unit 200 and the second driving signal may be output from a second output terminal OUT2 of the piezo driving unit 200.

For example, the piezo driving unit 200 may drive the piezo actuator 300 by filtering the analog control signal and generating the first and second driving signals having a phase difference of 180° from each other to apply the first and second driving signals to both terminals of the piezo actuator 300.

FIG. 4A is a graph illustrating an analog control signal output from the digital to analog converting unit 120 and FIG. 4B is a graph illustrating a signal output from the filtering unit 210.

Referring to FIGS. 3, 4A, and 4B, the analog control signal has a level varied in a step shape in the preset range according to the digital control signal having the number of bits which are sequentially increased or decreased. For example, the filtering unit 210 may generate the signal as shown in FIG. 4B by filtering the analog control signal as shown in FIG. 4A.

The amplifying unit 220 may perform the non-inverting amplification and the inverting amplification for the signal filtered by the filtering unit 210 as shown in FIG. 4B to generate the first driving signal and the second driving signal and output the first driving signal and the second driving signal through the first output terminal OUT1 and the second output terminal OUT2, respectively.

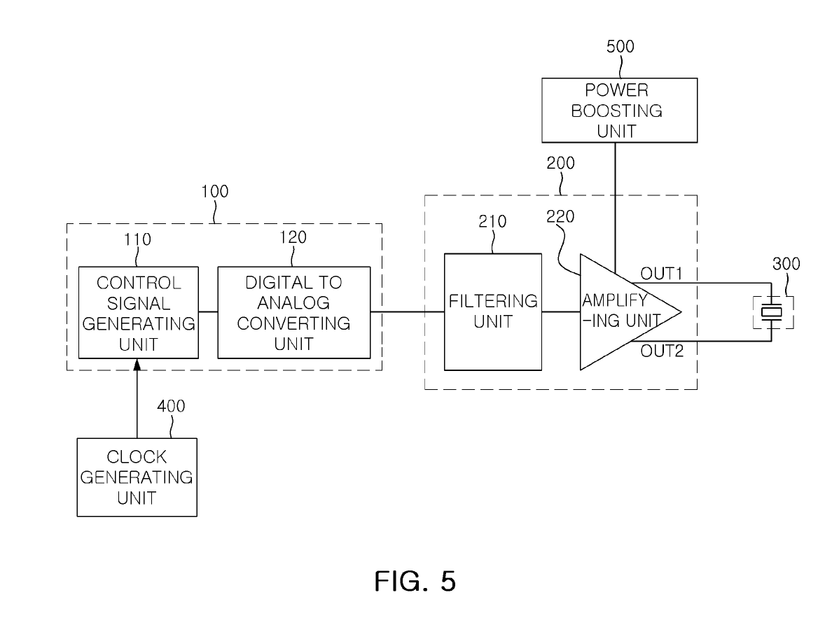

FIG. 5 is a block diagram illustrating the driving apparatus of the piezo actuator shown in FIG. 1 in more detail.

Referring to FIG. 5, the driving apparatus of the piezo actuator according to an exemplary embodiment of the present disclosure may further include a power boosting unit 500. The power booting unit 500 may provide a boosted voltage to the amplifying unit 220.

The power boosting unit 500 may receive a low voltage (e.g., 3V to 5V) provided from an external power source and boost the received low voltage to a high voltage (e.g., 100V) to provide the boosted voltage to the amplifying unit 220.

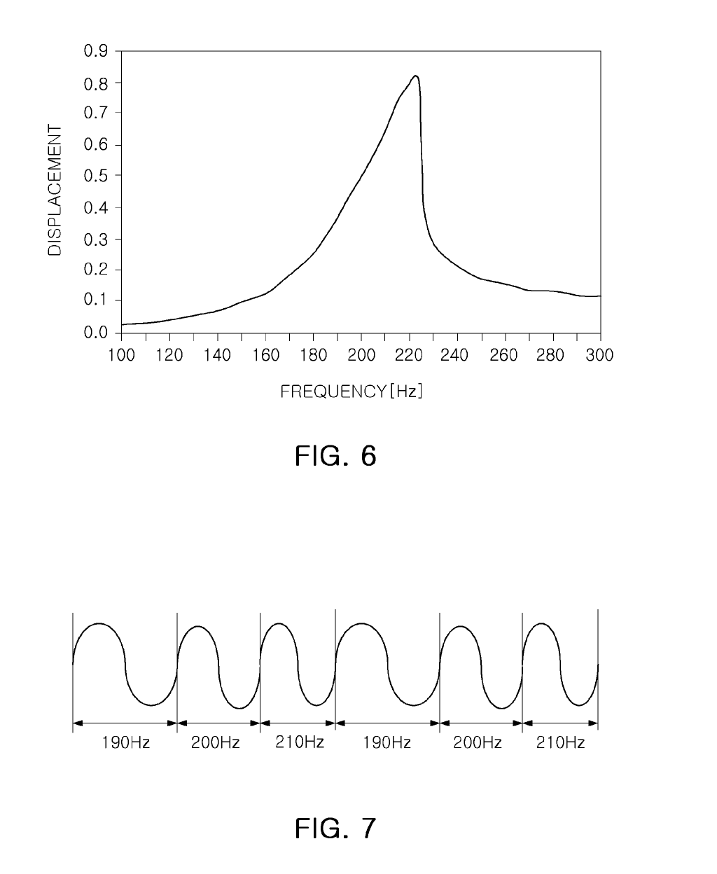

FIG. 6 is a graph illustrating displacement in a case in which the piezo actuator is driven by a driving apparatus of a piezo actuator according to the related art.

Referring to FIG. 6, it may be appreciated that the piezo actuator has the greatest displacement at 225 Hz. In this case, 225 Hz corresponds to the natural vibration frequency and the piezo driving unit may use the natural vibration frequency as the driving frequency signal and vibrate the piezo actuator according to a driving signal having the driving frequency signal.

However, in the case in which the driving signal having a fixed frequency is used, variations in characteristics and deterioration of the piezo actuator may be caused depending on the external temperature, an operating period of time, or the like of the piezo actuator, thereby causing a problem of product reliability.

Further, since the driving frequency signal needs to be necessarily adjusted according to deviations in characteristics of the piezo actuator, mass-production efficiency may be decreased.

On the other hand, since the driving apparatus of the piezo actuator according to an exemplary embodiment of the present disclosure may drive the piezo actuator 300 according to the driving frequency signal generated by sweeping the natural vibration frequency according to the driving clock provided from the clock generating unit 400, the above-mentioned problem may be solved.

In further detail, the frequency controlling unit 100 among the components of the driving apparatus of the piezo actuator according to an exemplary embodiment of the present disclosure may generate a control signal having the driving frequency signal by sweeping the natural vibration frequency according to the driving clock provided from the clock generating unit 400.

In this case, an example of the driving frequency signal may be in the range of ±5% of the natural vibration frequency. For example, when the natural vibration frequency is 200 Hz, the driving frequency signal may be in the range of 190 Hz to 210 Hz. Meanwhile, the natural vibration frequency refers to a frequency of a case in which the piezo actuator is vibrated at the maximum displacement.

For example, the frequency controlling unit 100 may generate a plurality of driving frequencies within the range of ±5% of the natural vibration frequency. In this case, the frequency controlling unit 100 may continuously or periodically generate the driving frequency signal and provide the generated driving frequency signal to the piezo driving unit 200.

The frequency controlling unit 100 may seta sweep range capable of securing sufficient reliability in accordance with characteristics of the piezo actuator 300 even in the case in which a temperature deviation, or the like is present and generate the driving frequency signal according to the sweep range.

In this case, the sweep range may be determined according to the driving clock provided from the clock generating unit 400. Therefore, the clock generating unit 400 may generate the driving clock by converting a preset reference voltage in accordance with characteristics of the piezo actuator 300.

In this case, an average displacement of the piezo actuator 300 for each sweep period becomes equal.

Therefore, even in the case in which conditions such as an environment, a temperature, and the like around the piezo actuator 300 are varied, the piezo actuator 300 is driven according to the driving frequency signal generated by sweeping the natural vibration frequency, such that reliability may be secured and the efficiency problem in the mass-production may be solved.

FIG. 7 is a graph illustrating a natural vibration frequency that is swept and output by the driving apparatus of the piezo actuator according to an exemplary embodiment of the present disclosure.

In this case, in the case in which the natural vibration frequency, for example, a frequency having the maximum displacement when piezo actuator is vibrated, is 200 Hz by way of example, the frequency controlling unit 100 may output the driving frequency signal that is swept in the range of 190 Hz to 210 Hz as shown in FIG. 7.

Assuming that the reference clock has a frequency band of 10 MHz, the clock generating unit 400 may generate the driving clock by changing the reference clock to 10 MHz, 10.5 MHz, and 9.5 MHz for one period.

Next, the clock generating unit 400 may provide the driving clock to the frequency controlling unit 100 and the frequency controlling unit 100 may generate the driving frequency signal in the range of 190 Hz to 210 Hz by sweeping the natural vibration frequency (200 Hz) according to the driving clock.

Therefore, the frequency controlling unit 100 may provide the driving frequency signal generated by sweeping the natural vibration frequency according to the driving clock to the piezo driving unit 200, and the piezo driving unit 200 may drive the piezo actuator according to the driving frequency signal.

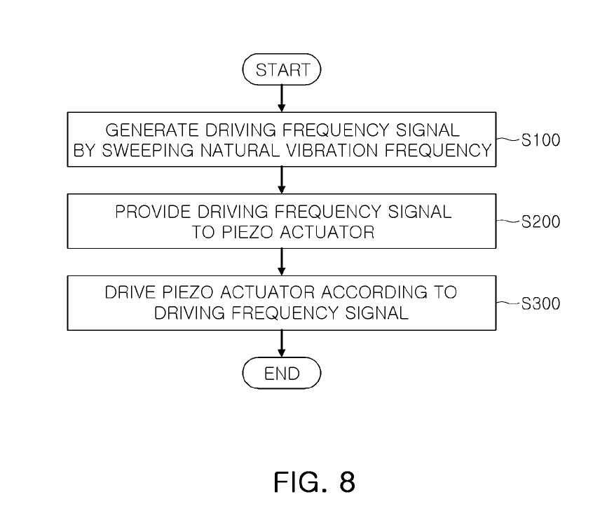

FIG. 8 is a flow chart illustrating a method of driving a piezo actuator according to an exemplary embodiment of the present disclosure.

Referring to FIG. 8, the method of driving a piezo actuator according to an exemplary embodiment of the present disclosure may include generating a driving frequency signal by sweeping a natural vibration frequency (S100), providing the driving frequency signal to the piezo actuator 300 (S200), and driving the piezo actuator 300 according to the driving frequency signal (S300). In this case, the driving frequency signal may be in the range of ±5% of the natural vibration frequency. By way of example, when the natural vibration frequency is 200 Hz, the driving frequency signal may be in the range of 190 Hz to 210 Hz.

The generating of the driving frequency signal (S100) may include generating a driving clock by changing a reference clock, and the driving frequency signal may be generated by sweeping the natural vibration frequency according to the driving clock. In this case, the driving clock may be in a range of ±5% of the reference clock.

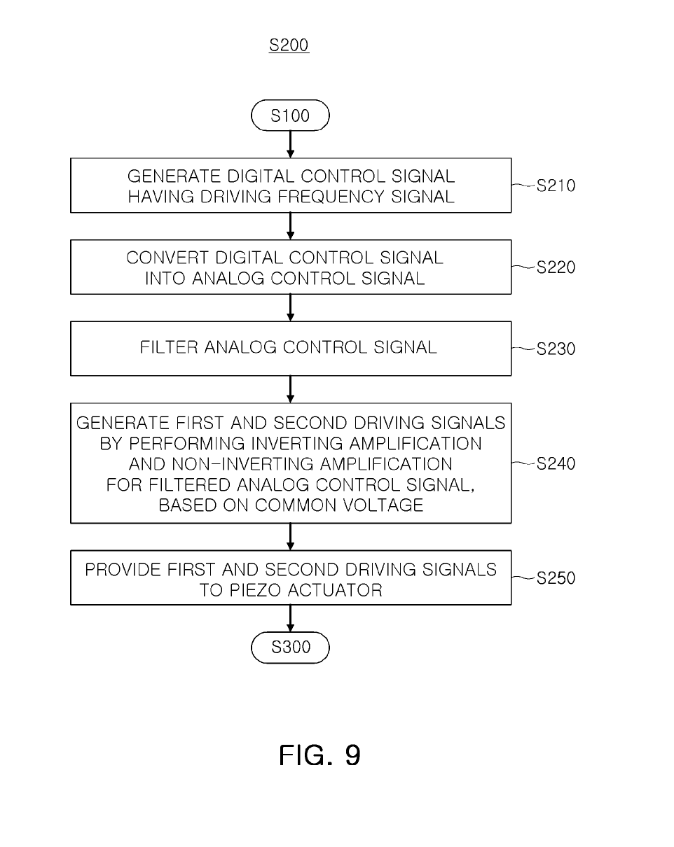

FIG. 9 is a flow chart illustrating a method of driving a piezo actuator according to an exemplary embodiment of the present disclosure.

Referring to FIG. 9, the providing of the driving frequency signal to the piezo actuator 300 (S200) may include generating a digital control signal having the driving frequency signal (S210), converting the digital control signal into an analog control signal (S220), filtering the analog control signal (S230), generating first and second driving signals by performing inverting amplification and non-inverting amplification for the filtered analog control signal, based on a common voltage (S240), and providing the first and second driving signals to the piezo actuator (S250).

As set forth above, according to exemplary embodiments of the present disclosure, the driving apparatus of the piezo actuator may constantly maintain displacement characteristics even in the case of the temperature and environment changes, by driving the piezo actuator using the driving frequency signal generated by sweeping the natural vibration frequency.

In addition, when the products are mass-produced, deterioration in mass-production efficiency may be prevented and product reliability may be improved.

While exemplary embodiments have been shown and described above, it will be apparent to those skilled in the art that modifications and variations could be made without departing from the spirit and scope of the present disclosure as defined by the appended claims.

What is claimed is:

1. A driving apparatus of a piezo actuator, the driving apparatus comprising:
a frequency controlling unit generating a driving frequency signal by sweeping a natural vibration frequency; and
a piezo driving unit driving the piezo actuator according to the driving frequency signal by providing the driving frequency signal to the piezo actuator,
wherein the driving frequency signal is in the range of ±5% of the natural vibration frequency.

2. The driving apparatus of the piezo actuator of claim 1, further comprising a clock generating unit generating a driving clock by changing a reference clock in the range of ±5% and providing the driving clock to the frequency controlling unit.

3. The driving apparatus of the piezo actuator of claim 2, wherein the frequency controlling unit generates the driving frequency signal by sweeping the natural vibration frequency according to the driving clock.

4. The driving apparatus of the piezo actuator of claim 1, wherein the piezo actuator is vibrated at relative maximum displacement at the natural vibration frequency.

5. The driving apparatus of the piezo actuator of claim 1, wherein the frequency controlling unit includes:
a control signal generating unit generating a digital control signal having the driving frequency signal; and
a digital to analog converting unit converting the digital control signal into an analog control signal.

6. The driving apparatus of the piezo actuator of claim 1, wherein the piezo driving unit includes:
a filtering unit filtering the analog control signal; and
an amplifying unit generating first and second driving signals by performing inverting amplification and non-inverting amplification on the analog control signal provided from the filtering unit, based on a common voltage.

7. The driving apparatus of the piezo actuator of claim 6, wherein the piezo driving unit applies the first and second driving signals to both terminals of the piezo actuator.

8. The driving apparatus of the piezo actuator of claim 1, wherein the driving frequency signal has a range of 190 Hz to 210 Hz.

9. A method of driving a piezo actuator, the method comprising:
generating a driving frequency signal by sweeping a natural vibration frequency;
providing the driving frequency signal to the piezo actuator; and
driving the piezo actuator according to the driving frequency signal,
wherein the driving frequency signal is in a range of ±5% of the natural vibration frequency.

10. The method of claim 9, wherein the generating of the driving frequency signal comprises generating a driving clock by changing a reference clock, the natural vibration frequency being swept according to the driving clock and the driving clock being in the range of ±5% of the reference clock.

11. The method of claim 9, wherein the providing of the driving frequency signal to the piezo actuator comprises:
generating a digital control signal having the driving frequency signal; and
converting the digital control signal into an analog control signal.

12. The method of claim 11, wherein the providing of the driving frequency signal to the piezo actuator further comprises:
filtering the analog control signal;
generating first and second driving signals by performing inverting amplification and non-inverting amplification for the filtered analog control signal, based on a common voltage; and
providing the first and second driving signals to the piezo actuator.

13. The method of claim 9, wherein the piezo actuator is vibrated at relative maximum displacement at the natural vibration frequency.

14. The method of claim 9, wherein the driving frequency signal has a range of 190 Hz to 210 Hz.
